(19) United States
(12) Patent Application Publication
(10) Pub. No.: US 2006/0113676 A1
(43) Pub. Date: Jun. 1, 2006

(54) Semiconductor device and method of manufacture thereof

(75) Inventors: Kazuhito Ichinose, Tokyo (JP); Akie Yutani, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/269,799

(22) Filed: Nov. 9, 2005

(30) Foreign Application Priority Data
Nov. 30, 2004 (JP) 2004-345349

(51) Int. Cl. H01L 23/48

(52) U.S. Cl. 257/763

(57) ABSTRACT

A barrier metal layer having a two-layer structure of a titanium film and a titanium nitride film is formed on the inner surface of a through hole. The titanium film and the titanium nitride film are formed on a main surface of an interlayer insulating film as well. In forming the barrier metal layer, a deposition device is used that is capable of high-directivity sputtering using a titanium target, and includes a substrate bias system biasing a semiconductor substrate to a high frequency voltage to attract sputter particles from the titanium target to the semiconductor substrate. This allows the titanium nitride film to be formed as an amorphous metal film.

### BACKGROUND OF THE INVENTION

1. Field of the Invention

This invention relates to semiconductor devices and methods of manufacture thereof, and more specifically to semiconductor devices having a multilevel wiring structure of aluminum wiring layers that are electrically connected by a tungsten plug and methods of manufacture thereof.

2. Description of the Background Art

Among known semiconductor devices having a multilevel wiring structure is a configuration in which aluminum wiring layers are electrically connected by a tungsten plug.

The multilevel wiring structure includes a plurality of structures vertically each of which is provided with upper and lower wiring layers with an interlayer insulating film on a semiconductor substrate therebetween.

Aluminum wiring layers are commonly used as the wiring layers. The upper and lower aluminum wiring layers have been electrically connected in recent years by using a tungsten plug that is formed by filling a through hole passing through an interlayer insulating film with a tungsten layer.

However, as wiring patterns become denser due to the shrinking of semiconductor devices in recent years, the occurrence of the so-called “displacement” has become inevitable in which the forming position of a through hole is displaced from over the lower wiring layer due to a mask misalignment in a photolithography process for providing the thorough hole in an interlayer insulating film.

If a wiring width is increased in order to prevent the displacement, then it would go against the shrinking of semiconductor devices.

If the through hole is reduced in order to prevent the displacement effectively, then a contact area to the wiring layer would be reduced to increase contact resistance. Thus, this is not a desirable option either.

Therefore, it has been difficult to avoid the occurrence of displacement in semiconductor devices having denser wiring patterns. Even designs that accept the displacement have been put into effect recently.

That is, a semiconductor device is designed such that a margin of mask alignment in a photolithography process is set small, for example, to increase the possibility of the displacement occurring in a limited range. The limited range as used herein means setting the margin of mask alignment in such a way that the through hole does not completely deviate from over the wiring layer, but is at least partially positioned over the wiring layer even in the event of displacement.

When the displacement occurs in such limited range, the upper surface of the wiring layer is exposed to part of the bottom surface of the through hole, and the side surface of the wiring layer is exposed to part of the side surface of the through hole. Filling the through hole with a tungsten layer, a contact area between the wiring layer and the tungsten layer can be ensured to the same degree or more as when the displacement does not occur.

When using aluminum wiring layers as the wiring layers and establishing electrical connection between the wiring layers by a tungsten plug, a barrier metal layer having a two-layer structure of a titanium film and a titanium nitride film has been conventionally formed on the inner surface (including the side surfaces and bottom surface) of a through hole, as is described in Japanese Patent Application Laid-Open No. 2003-303881 (paragraphs [0002] to [0008]), for example.

JP 2003-303881 discloses using a sputtering method to form the titanium film and titanium nitride film, but also indicates that when using the sputtering method, the barrier metal layer can be formed on the bottom surface but is hard to form on the side surfaces of a through hole having an aspect ratio of 2 or more.

This means there is a high possibility of the barrier metal layer not being formed on the side surface of the wiring layer being exposed to the side surface of the through hole in the event of displacement of the through hole.

A tungsten film to fill the through hole is formed by CVD (chemical vapor deposition). When the tungsten film is formed without the barrier metal layer being formed, reaction occurs between tungsten hexafluoride (WF₆) used in forming the tungsten film and aluminum of the wiring layer to form aluminum fluoride (AlF₃), causing a void to appear. It is indicated in JP 2003-303881 that a void leads to a reduction in reliability of electrical connection between the tungsten plug and the aluminum wiring layers, and an increase in contact resistance.

In addition, it is indicated that fluorine (F) reacts easily with titanium to form titanium fluoride (TiF₃, TiF₄), causing a reduction in adhesive strength and easy separation between a titanium film and titanium nitride film in a publication entitled “Nanometer scale material analysis using Fourier Transform Mapping”, ISSM 2000 proceeding, by Tadashi Ide and Haruko Tamegai, pp 265-268.

As described above, there have been problems with conventional semiconductor devices in that there is a possibility of a barrier metal layer not being formed on some part in a through hole, and that part causes a reduction in reliability of electrical connection between a tungsten plug and aluminum wiring layers, and an increase in contact resistance.

### SUMMARY OF THE INVENTION

It is an object of this invention to provide a semiconductor device in which aluminum wiring layers are electrically connected by a tungsten plug with high reliability and low contact resistance, with a barrier metal layer being formed on the whole inner surface of a through hole.

In an aspect of the invention, a semiconductor device having a multilevel wiring structure includes: a multilevel wiring layer provided on a semiconductor substrate; an interlayer insulating film provided between a lower wiring layer and an upper wiring layer, the lower and upper wiring layers being formed of aluminum wiring layers and forming the multilevel wiring layer; and a contact part passing through the interlayer insulating film to electrically connect the lower and upper wiring layers. The contact part includes: a through hole passing through the interlayer insulating film to reach the top of the lower wiring layer; a barrier metal layer provided along an inner surface of the through hole; and a tungsten plug filling the through hole defined by the barrier metal layer. The barrier metal layer includes an amorphous metal film.

The amorphous metal film included in the barrier metal layer provided along the inner surface of the through hole prevents diffusion of WF₆ or fluoride that occurs when the tungsten plug is formed by CVD, thus preventing WF₆ or fluoride from reacting with aluminum of the lower wiring layer to form AlF₃. Accordingly, the lower wiring layer and the tungsten plug can be electrically connected with high reliability and low contact resistance.

In another aspect of the invention, a method of manufacturing a semiconductor device having a multilevel wiring structure and including a multilevel wiring layer provided on a semiconductor substrate; an interlayer insulating film provided between a lower wiring layer and an upper wiring layer, the lower and upper wiring layers being formed of aluminum wiring layers and forming the multilevel wiring layer; and a contact part passing through the interlayer insulating film to electrically connect the lower and upper wiring layers, includes the following steps (a) to (e). Namely, the method includes the steps of (a) forming the interlayer insulating film to cover the lower wiring layer; (b) forming a through hole passing through the interlayer insulating film to reach the top of the lower wiring layer; (c) forming a barrier metal layer along an inner surface of the through hole; (d) forming a tungsten plug in the through hole defined by the barrier metal layer; and (e) forming the upper wiring layer on the interlayer insulating film, to be connected to the tungsten plug. The step (c) includes the step of sputtering a metal material of the barrier metal layer using a DC magnetron sputter to generate sputter particles, while biasing the semiconductor substrate to a high frequency voltage to attract the sputter particles to the semiconductor substrate, thereby forming the barrier metal layer. A DC power of the DC magnetron sputter is set from 1 to 40 kW, a deposition temperature is set from room temperature to 400° C., and a high frequency power supplied to the semiconductor substrate is set to 1 kW or less. The step (d) includes the step of filling the through hole defined by the barrier metal layer with a tungsten film by CVD.

By sputtering the metal material of the barrier metal layer using the DC magnetron sputter to generate sputter particles, while biasing the semiconductor substrate to a high frequency voltage to attract the sputter particles to the semiconductor substrate, the barrier metal layer can be formed as an amorphous metal film and can be formed uniformly on the side surfaces of a through hole having a large aspect ratio. This prevents diffusion of WF₆ or fluoride that occurs when the tungsten plug is formed, thus preventing WF₆ or fluoride from reacting with aluminum of the lower wiring layer to form AlF₃. Accordingly, the lower wiring layer and the tungsten plug can be electrically connected with high reliability and low contact resistance.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 6 are cross-sectional views illustrating the manufacturing steps of a semiconductor device according to a preferred embodiment of this invention;

FIG. 7 is a cross-sectional view illustrating the structure of the semiconductor device according to the preferred embodiment; and

FIGS. 8 and 9 are cross-sectional views illustrating the structures of modified examples of the semiconductor device according to the preferred embodiment.

### DESCRIPTION OF THE PREFERRED EMBODIMENTS

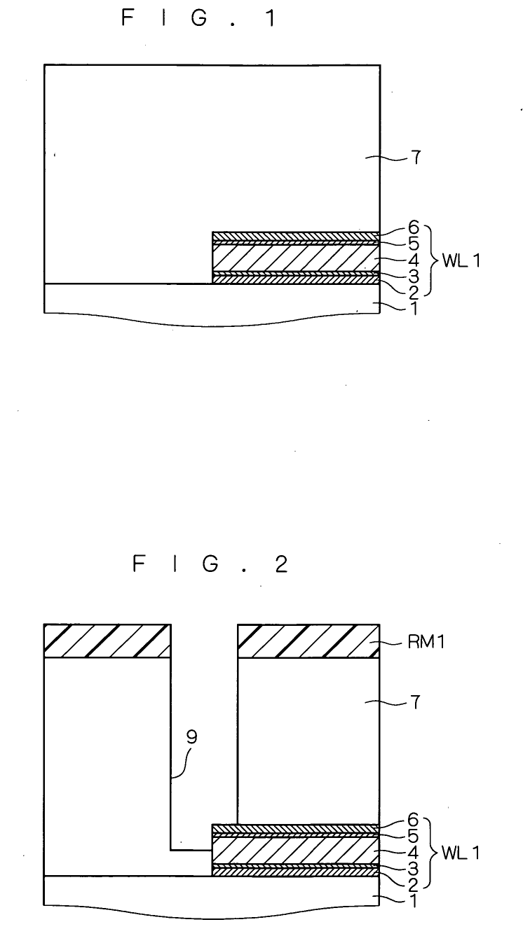

A preferred embodiment according to this invention will be described with reference to FIGS. 1 to 7. FIGS. 1 to 7 are cross-sectional views illustrating the manufacturing steps in order. FIG. 7 of the final step illustrates part of a semiconductor device 100 pertinent to this invention.

A feature of this invention is described by referring to the manufacturing method of the semiconductor device 100 illustrated in FIG. 1 to 7.

In a FIG. 1 step, a semiconductor device such as a transistor is formed on a semiconductor substrate not shown, and then an interlayer insulating film 1 is formed to cover the semiconductor substrate and the semiconductor device.

Next, a multilevel metal film is formed on the interlayer insulating film 1 by depositing a titanium film 2, a titanium nitride film 3, an aluminum film 4 basically made of aluminum and formed of an alloy film and the like including copper, a titanium film 5, and a titanium nitride film 6 in order by the sputtering method. A resist mask (not shown) having a desired wiring pattern is then formed thereon in a photolithography step.

Then, the multilevel metal film is patterned by dry etching using the resist mask, thus obtaining an aluminum wiring layer WL1. The aluminum wiring layer WL1 may in some cases be called a lower wiring layer.

The formation of the aluminum wiring layer WL1 is followed by forming an interlayer insulating film 7 to cover the aluminum wiring layer WL1 and the interlayer insulating film 1.

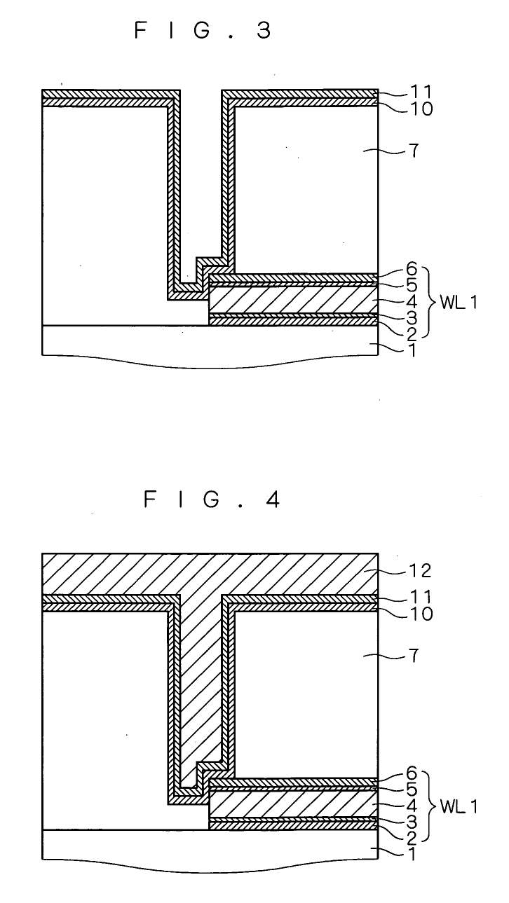

Next, in a FIG. 2 step, a resist material is applied to the interlayer insulating film 7 to form a resist mask RM1 having a predetermined through hole pattern in a photolithography step.

The interlayer insulating film 7 is then selectively dry-etched using the resist mask RM1, thus forming a through hole 9.

In forming the resist mask RM1, a margin of exposure mask alignment is set small to increase the possibility that the forming position of the through hole 9 is displaced from over the aluminum wiring layer WL1, namely, the “displacement” occurs, in a limited range.

The result is that as illustrated in FIG. 2, a bottom surface position of the through hole 9 is displaced from over the aluminum wiring layer WL1, whereby the upper surface of the titanium nitride film 6 is exposed to part of the bottom surface of the through hole 9, and the side surfaces of the titanium nitride film 6, titanium film 5 and aluminum film 4 are exposed to part of the side surface of the through hole 9. The exposed portion of the side surface of the aluminum wiring layer WL1 may in some cases be called a slit portion.

Then, after removing the resist mask RM1 by ashing, a barrier metal layer having a two-layer structure of a titanium film 10 and a titanium nitride film 11 is formed on the inner surface of the through hole 9 in a FIG. 3 step. The titanium film 10 and the titanium nitride film 11 are formed on the main surface of the interlayer insulating film 7 as well.

In forming the barrier metal layer, a deposition device is used that is capable of high-directivity sputtering using a titanium target, and includes a substrate bias system biasing a semiconductor substrate to a high frequency voltage to attract sputter particles from the titanium target to the semiconductor substrate.

The sputtering of the titanium target is done by a DC magnetron sputter.

The DC magnetron sputter generates high-density plasma by generating E×B drift in electrons by a DC voltage applied to a metal target and a magnetic field formed in parallel to the metal target, and sputters the metal target by ions in the plasma.

By performing the high-directivity sputtering using the DC magnetron sputter while biasing the semiconductor substrate to a high frequency voltage to actively attract the sputter particles to the semiconductor substrate, the titanium nitride film 11 is formed as an amorphous metal film. This is a feature of this invention.

Namely, it was difficult with conventional methods of forming a barrier metal layer using high-directivity sputtering to form a barrier metal layer on the side surfaces of a through hole having an aspect ratio of 2 or more, and especially to form a barrier metal layer uniformly on the slit portion (exposed portion of the side surface of a wiring layer) in the event of displacement of the through hole.

Even if a barrier metal layer can be formed on the slit portion, a titanium nitride film is a crystalline film, so tungsten hexafluoride (WF₆) used in forming the tungsten film diffuses along a crystal grain boundary, causing fluorine (F) to react with the aluminum wiring layer.

Meanwhile, the titanium nitride film 11, which is amorphous, does not have a crystal grain boundary, and serves as a diffusion prevention film of WF₆ and fluorine. While the through hole 9 may in some cases have a large aspect ratio as high as 4 or more in the semiconductor device according to this invention, the titanium nitride film 11 and the titanium film 10 that are formed by actively attracting the sputter particles to the semiconductor substrate are formed uniformly on the side surfaces of the through hole 9. Accordingly, the barrier metal layer can be formed uniformly on the slit portion even in the event of displacement of the through hole 9.

This prevents WF₆ or fluoride from reacting with aluminum of the wiring layer WL1 to form AlF₃ when a tungsten plug is formed later, thus preventing a reduction in reliability of electrical connection between the aluminum wiring layer WL1 and the tungsten plug to be formed later, and an increase in contact resistance.

Although fluorine reacts easily with titanium, the titanium nitride film 11 which is amorphous covers the titanium film 10 to prevent fluorine from diffusing to reach the titanium film 10, thus preventing a reduction in adhesive strength and separation that results between the titanium film 10 and the titanium nitride film 11.

The deposition conditions for the titanium film 10 and the titanium nitride film 11 are described by way of example.

A titanium target is used as a metal target, and a DC power of the DC magnetron sputter is set from 1 to 40 kW. A high frequency power applied to the semiconductor substrate is set from 0 to 1 kW, and the temperature of a stage for mounting the semiconductor substrate, namely, a deposition temperature, is set from room temperature to 400° C. The above-described range indicates a possible case where the high frequency power sufficiently near 0 may be applied, though the effect of actively attracting sputter particles to the semiconductor substrate cannot be expected when the high frequency power is 0. The titanium film 10 and/or the titanium nitride film 11 can be made amorphous by combinations of parameters in the above-described range.

In forming the titanium film 10 under the above conditions, argon gas is introduced into a processing chamber having been temporarily evacuated, and pressure in the processing chamber is controlled in a range of 0.4 to 1.0 Pa (pascal). The best conditions for uniformity of film thickness on the semiconductor substrate are then selected.

In forming the titanium nitride film 11, mixed gas of nitrogen and argon is introduced into the processing chamber, and the pressure in the processing chamber is controlled in a range of 0.4 to 1.0 Pa. Here, a flow rate of nitrogen is controlled to be 50% or higher of that of the mixed gas. The best conditions for uniformity of film thickness on the semiconductor substrate are then selected.

The titanium film 10 is formed by applying a high frequency bias to the semiconductor substrate under the above conditions, and is therefore made amorphous. It is not required, however, that the titanium film 10 be amorphous.

As described above, the metal films are deposited by PVD (physical vapor deposition) in this application by using the DC magnetron sputter for supplying metal elements. The use of PVD is advantageous over other methods in the following respects:

Namely, when forming a titanium nitride film in a through hole by the CVD, TiCl₄—TiN is used as source gas and a deposition temperature in such case is 600° C. or higher. It would therefore be unsuitable for a titanium nitride film to be formed on the inner surface of the through hole engaged in an aluminum wiring layer. On the other hand, a titanium nitride film can be formed without affecting the aluminum wiring layer WL1 by the PVD having a stage temperature being in a range of room temperature to 400° C.

Further, when forming a titanium nitride film by MOCVD (metal organic CVD) using TDMAT (tetrakis dimethyl amino titanium) having a deposition temperature of 450° C. or lower, impurities included in the titanium nitride film formed by the MOCVD are emitted as gas when a tungsten film is deposited next by the CVD to fill a through hole, inhibiting growth of the tungsten film. On the other hand, gas emission that would interfere with the deposition of the tungsten film does not occur in the PVD because no impurities are included in the titanium nitride film 11.

The titanium nitride film 11 serves not only as a diffusion prevention film of WF₆ and fluorine, but as a seed film for growth of the tungsten film.

Attention now returns to the manufacturing method with reference to the drawings.

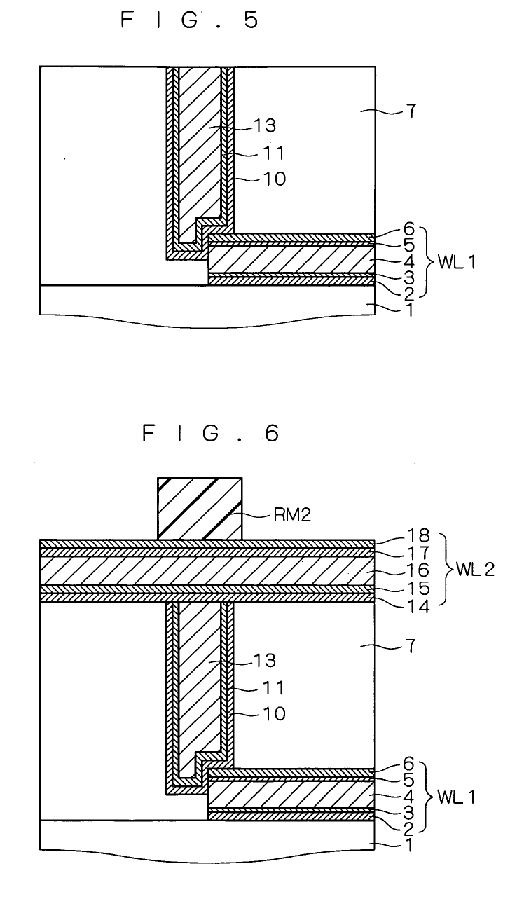

After forming the titanium nitride film 11, a tungsten film 12 is deposited by the CVD to fill the through hole 9, as illustrated in FIG. 4. The tungsten film 12 is formed on the main surface of the interlayer insulating film 7 as well.

Then, the tungsten film 12, the titanium nitride film 11 and the titanium film 10 positioned on the main surface of the interlayer insulating film 7 are removed by CMP (chemical mechanical polishing) to expose the main surface of the interlayer insulating film 7. Thus obtained is a FIG. 5 structure where a tungsten plug 13 is buried in the through hole 9.

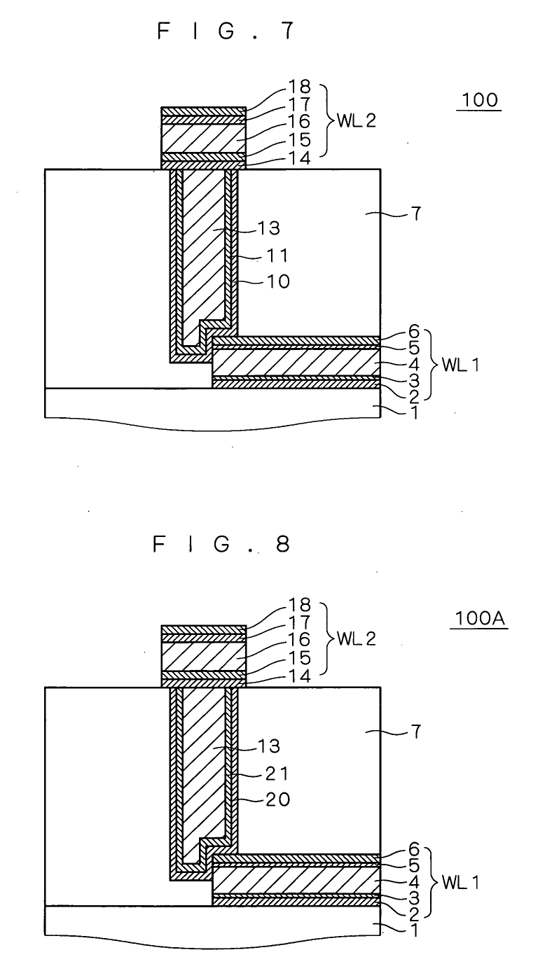

Next, in a FIG. 6 step, a multilevel metal film is formed on the interlayer insulating film 7 by depositing a titanium film 14, a titanium nitride film 15, an aluminum film 16 formed of an alloy film including aluminum and copper or simply made of aluminum, a titanium film 17, and a titanium nitride film 18 in order by the sputtering method. A resist mask RM2 having a desired wiring pattern is then formed thereon in a photolithography step.

Then, the multilevel metal film is patterned by dry etching using the resist mask RM2, thus obtaining an aluminum wiring layer WL2 connected to the tungsten plug 13, as illustrated in FIG. 7. The aluminum wiring layer WL2 may in some cases be called an upper wiring layer. The through hole 9, the titanium film 10, the titanium nitride film 11 and the tungsten plug 13 are generally called a contact part for electrically connecting the lower and upper wiring layers.

Processing then continues by repeating formation of a further interlayer insulating film on the interlayer insulating film 7, and formation of a tungsten plug that electrically connects the aluminum wiring layer WL2 and a further upper aluminum wiring layer by the same steps as illustrated in FIGS. 1 to 7, thus finally obtaining the semiconductor device 100. The semiconductor device 100 includes other structures than the multilevel wiring layers in the interlayer insulating films, which are formed simultaneously with the multilevel wiring layers. Since the other structures are not essentially relevant to this invention, the descriptions thereof are omitted.

<First Modification>

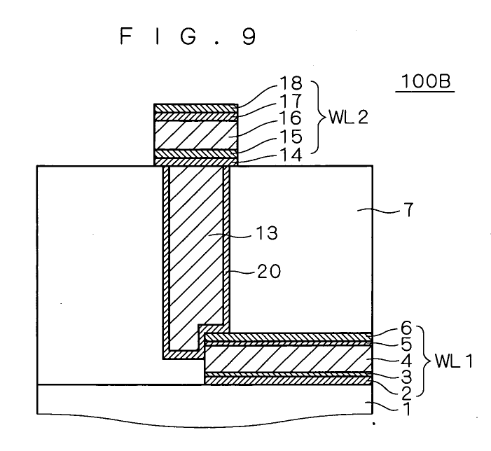

In the preferred embodiment described above, the barrier metal layer having a two-layer structure of the titanium film 10 and the titanium nitride film 11 is formed by way of example on the inner surface of the through hole 9. Alternatively, the barrier metal layer may have a two-layer structure of a tungsten nitride film 20 and a tungsten film 21, as in a semiconductor device 100A illustrated in FIG. 8.

Like the titanium film 10 and the titanium nitride film 11, the tungsten nitride film 20 and the tungsten film 21 are formed by actively attracting the sputter particles to the semiconductor substrate, and are therefore made amorphous.

The tungsten nitride film 20, which is amorphous, does not have a crystal grain boundary, and serves as a diffusion prevention film of WF₆ and fluorine when the tungsten plug is formed later. This prevents fluorine from passing through the barrier metal layer to react with the aluminum wiring layer WL1 to form AlF₃, thus preventing a reduction in reliability of electrical connection between the aluminum wiring layer WL1 and the tungsten plug to be formed later, and an increase in contact resistance.

The tungsten film 21 tends to become a seed film for growth of the tungsten film formed by the CVD when the tungsten plug is formed. Accordingly, the tungsten film 21 should be formed over the tungsten nitride film 20 to grow the tungsten plug more smoothly.

The deposition conditions for the tungsten nitride film 20 and the tungsten film 21 are described by way of example.

A tungsten target is used as a metal target, and a DC power of the DC magnetron sputter is set from 1 to 40 kW. A high frequency power applied to the semiconductor substrate is set from 0 to 1 kW, and the temperature of the stage for mounting the semiconductor substrate is set from room temperature to 400° C.

In forming the tungsten nitride film 20 under the above conditions, mixed gas of nitrogen and argon is introduced into a processing chamber, and pressure in the processing chamber is controlled in a range of 0.4 to 1.0 Pa. Here, a flow rate of nitrogen is controlled to be 50% or higher of that of the mixed gas. The best conditions for uniformity of film thickness on the semiconductor substrate are then selected.

In forming the tungsten film 21, argon gas is introduced into the processing chamber having been temporarily evacuated, and the pressure in the processing chamber is controlled in a range of 0.4 to 1.0 Pa. The best conditions for uniformity of film thickness on the semiconductor substrate are then selected.

The sequence of deposition of the tungsten nitride film 20 first and the tungsten film 21 thereafter on the inner surface of the through hole 9, as described above, may be reversed.

Namely, it may be that the tungsten film 21 is formed first on the inner surface of the through hole 9, and the tungsten nitride film 20 is formed thereon. Again in this case, the tungsten nitride film 20 which is amorphous serves as a diffusion prevention film of WF₆ and fluorine when the tungsten plug is formed, thus preventing fluorine from passing through the barrier metal layer to react with the aluminum wiring layer WL1 to form AlF₃.

The tungsten nitride film 20 also serves as a seed film for growth of the tungsten film formed by the CVD.

<Second Modification>

In the first modification described above, the barrier metal layer in the through hole 9 has a two-layer structure of the tungsten nitride film 20 and the tungsten film 21. Alternatively, the barrier metal layer may have a single-layer structure.

FIG. 9 illustrates a semiconductor device 100B including a barrier metal layer having a single-layer structure of the tungsten nitride film 20.

The tungsten nitride film 20 is formed by actively attracting the sputter particles to the semiconductor substrate, and is therefore made amorphous.

The tungsten nitride film 20, which is amorphous, does not have a crystal grain boundary, and serves as a diffusion prevention film of WF₆ and fluorine when the tungsten plug is formed later. This prevents fluorine from passing through the barrier metal layer to react with the aluminum wiring layer WL1 to form AlF₃, thus preventing a reduction in reliability of electrical connection between the aluminum wiring layer WL1 and the tungsten plug to be formed later, and an increase in contact resistance.

Although having a single-layer structure of the tungsten nitride film 20, the barrier metal layer in the through hole may naturally have a single-layer structure of the tungsten film 21.

The tungsten film 21 is formed by actively attracting the sputter particles to the semiconductor substrate, and is therefore made amorphous. The tungsten film 21 thus serves as a diffusion prevention film of WF₆ and fluorine.

<Third Modification>

The barrier metal layer in the through hole 9 has a two-layer structure of the titanium film 10 and the titanium nitride film 11 in the preferred embodiment, a two-layer structure of the tungsten nitride film 20 and the tungsten film 21 in the first modification, and includes one of the tungsten nitride film 20 and the tungsten film 21 in the second modification. These are exemplary metals, and do not restrict in any way the metals usable in this application.

Namely, the barrier metal layer in the through hole 9 may have a two-layer structure of a refractory metal and a nitride film of that metal, the high-melting metal being selected from among a group including vanadium (V), chromium (Cr), zirconium (Zr), niobium (Nb), molybdenum (Mo), ruthenium (Ru), hafnium (Hf), tantalum (Ta), and rhenium (Re). Alternatively, the barrier metal layer in the through hole 9 may simply be made of one metal selected from among the above group.

In all cases, the same effects as the preferred embodiment and the first and second modifications can be attained by using a deposition device that is capable of high-directivity sputtering, and includes a high-frequency-substrate-bias system to attract sputter particles from a metal target to the semiconductor substrate.

The deposition conditions are such that a DC power of the DC magnetron sputter is from 1 to 40 kW, a high frequency power applied to the semiconductor substrate is from 0 to 1 kW, and the temperature of the stage for mounting the semiconductor substrate is from room temperature to 400° C. The metal selected from among the above group is naturally used as a target material.

In forming a metal nitride film under the above conditions, mixed gas of nitrogen and argon is introduced into a processing chamber, and pressure in the processing chamber is controlled in a range of 0.4 to 1.0 Pa. Here, a flow rate of nitrogen is controlled to be 50% or higher of that of the mixed gas. The best conditions for uniformity of film thickness on the semiconductor substrate are then selected.

In forming a metal film, argon gas is introduced into the processing chamber having been temporarily evacuated, and the pressure in the processing chamber is controlled in a range of 0.4 to 1.0 Pa. The best conditions for uniformity of film thickness on the semiconductor substrate are then selected.

When adopting a two-layer structure using both of the metal nitride film and the metal film formed by this method, either one of the two films should be amorphous. When adopting a single-layer structure, the film should be amorphous no matter what metal is used.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device having a multilevel wiring structure, comprising:
a multilevel wiring layer provided on a semiconductor substrate;
an interlayer insulating film provided between a lower wiring layer and an upper wiring layer, said lower and upper wiring layers being formed of aluminum wiring layers and forming said multilevel wiring layer; and
a contact part passing through said interlayer insulating film to electrically connect said lower and upper wiring layers,
said contact part including:
a through hole passing through said interlayer insulating film to reach the top of said lower wiring layer;
a barrier metal layer provided along an inner surface of said through hole; and
a tungsten plug filling said through hole defined by said barrier metal layer,
said barrier metal layer including an amorphous metal film.

2. The semiconductor device according to claim 1, wherein
said barrier metal layer has a two-layer structure including a titanium film and a titanium nitride film, said titanium nitride film being provided over said titanium film, and at least said titanium nitride film being amorphous.

3. The semiconductor device according to claim 1, wherein
said barrier metal layer has a two-layer structure including a tungsten film and a tungsten nitride film, at least one of said tungsten film and said tungsten nitride film being amorphous.

4. The semiconductor device according to claim 3, wherein
said barrier metal layer includes said tungsten film provided over said tungsten nitride film, at least said tungsten nitride film being amorphous.

5. The semiconductor device according to claim 1, wherein
said barrier metal layer has a single-layer structure including one of an amorphous tungsten film and an amorphous tungsten nitride film.

6. The semiconductor device according to claim 1, wherein
said through hole is displaced from over said lower wiring layer partly in a bottom surface thereof exposing part of a side surface of said lower wiring layer to part of a side surface of said through hole, and
said barrier metal layer is provided to uniformly cover said bottom surface of said through hole and said side surface of said lower wiring layer being exposed to said side surface of said through hole.

7. A method of manufacturing a semiconductor device having a multilevel wiring structure, said semiconductor device comprising:
a multilevel wiring layer provided on a semiconductor substrate;
an interlayer insulating film provided between a lower wiring layer and an upper wiring layer, said lower and upper wiring layers being formed of aluminum wiring layers and forming said multilevel wiring layer; and
a contact part passing through said interlayer insulating film to electrically connect said lower and upper wiring layers,
said method comprising the steps of:
(a) forming said interlayer insulating film to cover said lower wiring layer;
(b) forming a through hole passing through said interlayer insulating film to reach the top of said lower wiring layer;
(c) forming a barrier metal layer along an inner surface of said through hole;
(d) forming a tungsten plug in said through hole defined by said barrier metal layer; and
(e) forming said upper wiring layer on said interlayer insulating film, to be connected to said tungsten plug,
said step (c) including the step of sputtering a metal material of said barrier metal layer using a DC magnetron sputter to generate sputter particles, while biasing said semiconductor substrate to a high frequency voltage to attract said sputter particles to said semiconductor substrate, thereby forming said barrier metal layer, a DC power of said DC magnetron sputter being set from 1 to 40 kW, a deposition temperature being set from room temperature to 400° C., and a high frequency power supplied to said semiconductor substrate being set to 1 kW or less, and
said step (d) including the step of filling said through hole defined by said barrier metal layer with a tungsten film by CVD.
